(19) United States
(12) Patent Application Publication
(10) Pub. No.: US 2011/0165389 A1
(43) Pub. Date: Jul. 7, 2011

(54) METHOD FOR FORMING CONDUCTIVE POLYMER PATTERN

(75) Inventor: Hiromu Taguchi, Aichi (JP)

(73) Assignees: TOAGOSEI CO., LTD., TOKYO (JP); TSURUMI SODA CO., LTD., YOKOHAMA-SHI (JP)

(21) Appl. No.: 12/996,932

(22) PCT Filed: Jul. 23, 2009
(86) PCT No.: PCT/JP09/63216

§ 371 Date: Mar. 18, 2011

(30) Foreign Application Priority Data
Jul. 29, 2008 (JP) 2008-194421

(51) Int. Cl. G03F 7/20; B32B 3/10

(52) U.S. Cl. 428/195.1; 430/324

(57) ABSTRACT

The present invention is a method for forming a patterned electroconductive layer containing an electroconductive polymer on a surface of a base body and is characterized in that a positive type photoresist composition containing a naphthoquinone diazide and a novolak resin is used, and that a developer containing a potassium ion at a concentration of 0.08 mol/l to 0.20 mol/l, and a coexistent sodium ion at a concentration of less than 0.1 mol/l is used for development of a resist film obtained by the positive type photoresist composition.

### FIELD OF THE INVENTION

The present invention relates to a method for forming a pattern of an electroconductive polymer using a positive type photoresist composition capable of forming a fine resist pattern which is high in sensitivity, high in resolution, high in adherence, and high in flexibility.

### BACKGROUND ART

In recent years, a substance typically abbreviated to “ITO” containing indium oxide and tin has been used as a transparent electroconductive film. Since indium is a rare element, various inorganic materials and organic materials have been extensively studied as an alternative to the ITO. Particularly, an electroconductive polymer, which is an organic material, is remarkable in improvement of electrical conductivity, and is thus hopefully expected as an alternative material to the ITO.

The electroconductive polymer has such a feature that the same possesses an electroconductivity, light transmissivity, and luminescent ability, and is higher than ITO in flexibility even after film formation. Thus the electroconductive polymer has been investigated for its application to a transparent electroconductive film, electrolytic capacitor, antistatic film, battery, organic EL, and the like, and has been practically used in part of them.

For example, an electronic paper as a displaying device is required to have a flexibility, and an electroconductive polymer has been investigated as a transparent electroconductive film therefor.

In the case of the electrolytic capacitor, it has been attempted to use an electroconductive solid such as a charge-transfer complex and a polythiophene instead of conventional electrolytic solutions. But it is enabled to fabricate an electrolytic capacitor excellent in frequency characteristic by adopting an electroconductive polymer which is more excellent in electroconductivity than the electrolytic solution. The electroconductive polymer to be used for an electrolytic capacitor is also required to be chemically and physically stable, and to be excellent in heat resistance.

Further, when a thin film of an electroconductive polymer is formed on a surface of a polymer film, it is possible to prevent static charge of a polymer film while keeping its transparency. Therefore, the polymer film is used as an antistatic film, antistatic container, or the like excellent in usability.

In a lithium polyaniline battery, a lithium ion polymer battery, and the like, an electroconductive polymer is used as a positive electrode of the secondary battery.

Meanwhile, an electroconductive polymer can be used, instead of platinum, as a counter electrode to titanium dioxide of a dye-sensitized solar cell. The dye-sensitized solar cell is expected as one, which is more inexpensive than presently prevailing silicon-based solar cells. Additionally, the electroconductive polymer is also being investigated for its application to an electronic device such as a diode and transistor.

Further, an organic EL is known which has an electroconductive polymer in a luminescent layer. It is possible to fabricate a flexible display by adopting an organic material instead of a glass. Furthermore, the electroconductive polymer can also be used as a hole transporting layer of the organic EL. The organic EL display is a self-luminous one, and is capable of realizing a light-weighted low-profile display having a wider viewing angle and a faster response speed, so that a development is being extensively advanced for the organic EL display as a promising flat panel display.

In this way, an electroconductive polymer is an important material for the electronics industry in the future. Techniques are necessary and indispensable which are capable of forming fine patterns similarly to ITO in adopting the electroconductive polymers.

Examples of fields requiring a pattern formation include those of outgoing lines in case of adopting an electroconductive polymer as electrodes for a touch panel, an electronic paper, and a polymeric EL display.

Several methods have been known each configured to form a pattern of an electroconductive polymer.

For example, a screen printing method, and a printing method utilizing an inkjet and the like are disclosed in Patent Document 1. Although such printing method is simple in production process because film formation is also conducted simultaneously with pattern formation, it is then required to prepare an electroconductive polymer in an ink state. However, the electroconductive polymer is apt to agglomerate, and it is difficult to prepare it in an ink state. In addition, the printing method has been problematic in accuracy of pattern, flatness and smoothness of surface, and the like.

Contrary, photolithography is a method configured to form a uniform film of an electroconductive polymer on a surface of a base body, thereafter form a photoresist pattern, and then etch a desired portion of the electroconductive polymer, thereby forming a pattern of an electroconductive polymer. This method is a widely used general-purpose technique capable of forming a pattern of an electroconductive polymer with a higher precision, though the number of processes is larger than those in the printing methods.

Patent Documents 2 and 3 disclose a method for forming a pattern of an electroconductive polymer by photolithography. Patent Document 2 discloses a method configured to form a metal layer on an electroconductive organic film, form a pattern of resist on the metal layer, subsequently etch the metal layer and the electroconductive organic film, and thereafter strip the pattern of resist, thereby forming an electrical conductor wiring pattern including the metal layer. However, this method indispensably requires the metal layer, and is not intended to form a pattern of an electroconductive polymer.

On the other hand, Patent Document 3 discloses a method configured to directly form a resist pattern on an electroconductive polymer, and etch the electroconductive polymer, thereby forming a pattern of an electroconductive polymer. It says that the resist usable in that case is an electron beam resist and a photoresist, that examples of the photoresist include “S1400” and “S1800” manufactured by Shipley Co. Inc., “AZ1500 Series”, “AZ1900 Series”, “AZ6100 Series”, “AZ4000 Series”, “AZ7000 Series” and “AZP4000 Series” (for example, “AZ4400” and “AZ4620”) manufactured by Hoechst Celanese Corp, that preferable photoresist is a naphthoquinone diazide-novolak type, and that example thereof includes “S1400”, “S1800”, “AZ1500 Series”, “AZ1900 Series”, “AZ4400 Series” and “AZ4620 Series”. In the Document, detail compositions are not described. There photoresists are mainly for the production of a semiconductor, and are not suitable for a flexible substrate. Further, a developer is not described which is required for the formation of a resist pattern and it is only indicated that “MF-312” manufactured by Shipley Co. Inc. is used. Patent Document 4 discloses “MF-312” is a metal free developer of an aqueous solution of tetramethylammonium hydroxide (TMAH).

Moreover, Patent Document 5 discloses a polyvinyl methyl ether as a water-soluble polymer compound, which can be blended in a photoresist containing a water-soluble naphthoquinone diazide compound. In addition, it is disclosed that the content of the water-soluble polymer compound is preferably in the range from 100 to 10,000 parts by weight based on 100 parts by weight of the water-soluble naphthoquinone diazide compound.

On the other hand, Patent Document 6 discloses that when a polyvinyl methyl ether is added as a plasticizer into a naphthoquinone diazide-novolak type photoresist, sensitivity is improved by about 15%. The polyvinyl methyl ether is used in an amount of 15.43% based on 20.12% of a novolak resin. Therefore, the corresponding content of the polyvinyl methyl ether is estimated to be 77 parts by weight based on 100 parts by weight of the novolak resin.

Further, in the case of a photoresist adopting a poly-p-hydroxystyrene which is known as an alkali-soluble resin and which is to be combined with an azide compound, the photoresist has resulted in a thick film having a thickness of exceeding 10 μm. This photoresist has been problematic in that the photoresist is exemplarily subjected to occurrence of cracks or is peeled when the photoresist is coated onto a base film of, for example, a polyethylene terephthalate and then wound therewith. Patent Document 6 describes that, when a copolymer of a poly-p-hydroxystyrene and a (meth)acrylic monomer is used instead of the poly-p-hydroxystyrene so as to improve an anticrack property to a resist, it is possible to combiningly use water or a polymer compound soluble in alkali. A polyvinyl alkyl ether is also disclosed as water or the alkali-soluble polymer compound (the preferable is a polyvinyl methyl ether). In Patent Document 7, the water and alkali-soluble polymer compound is capable of varying a softening temperature, an adherence, a characteristic relative to a developer, of the resist, and capable of optimizing the properties for a thickness of the resist, the process condition, and the like, such that the purpose is achievable when the addition amount of water or the polymer compound soluble in alkali is 20% or less by weight.

Constituent materials of substance bodies intended by the above photolithographic methods in Patent Documents 5, 6, 7 and the like are a metal such as silicon, aluminum and copper, and no photoresists have been known which are capable of intending and patterning electroconductive polymers.

As described above, although the techniques have been known which are configured to fabricate electroconductive patterns using electroconductive polymers, respectively, all the techniques are not suitable for a flexible substance body. Further, although several photoresists have been provided which are excellent in semiconductor application, all of them can be regarded as materials, which are never intended for patterning of electroconductive polymers. Namely, the situation is that all the techniques are insufficient for the recent demand to fabricate an electroconductive pattern on a flexible base body.

### PRIOR TECHNICAL DOCUMENT

### Patent Document

[Patent Document 1] JP-A 2005-109435
[Patent Document 2] JP-A H5-335718
[Patent Document 3] WO 1997/18944
[Patent Document 1] JP-A S61-118744
[Patent Document 2] JP-A S62-269136
[Patent Document 3] JP-A S61-7837
[Patent Document 1] JP-A H5-107752

### DISCLOSURE OF THE INVENTION

### Problems that the Invention is to Solve

The conventional photoresists have been problematic in that cracking and peeling are apt to be caused by bending of a base body in a process of exposing a flexible electroconductive film including an electroconductive polymer having a surface coated with an applicable photoresist by means of photolithography to thereby form a pattern. Further, adoption of tetramethylammonium hydroxide (TMAH) as a known developer brings about such a problem that an applicable resist is apt to be peeled at an interface between the resist and an electroconductive layer, thereby failing to form a pattern.

It is therefore an object of the present invention to provide a method for forming a pattern of an electroconductive polymer efficiently using a positive type photoresist composition capable of forming a fine resist pattern which is high in sensitivity, high in resolution, high in adherence, and high in flexibility, and a specific developer when a pattern of a flexible electroconductive layer is formed by photolithography.

### Means for Solving the Problems

The present inventors have investigated a composition of a photoresist and a composition of a developer which are cooperatively capable of providing a resist pattern without occurrence of cracks, and peeling, on a surface of an electroconductive film containing an electroconductive polymer, and have narrowly accomplished the present invention.

The present invention is as follows.

1. 1. A method for forming a pattern of an electroconductive polymer, characterized in that a positive type photoresist composition containing a naphthoquinone diazide compound and a novolak resin is used, and that a developer containing a potassium ion at a concentration of 0.08 mol/l to 0.20 mol/l, and a coexistent sodium ion at a concentration of less than 0.1 mol/l is used for development of a resist film obtained by the positive type photoresist composition.
2. The method for forming a pattern of an electroconductive polymer according to 1 above, wherein the method comprises sequentially,

an electroconductive layer forming process in which a composition for forming an electroconductive layer containing the electroconductive polymer is used to form an electroconductive layer on a surface of a base body,

a film forming process in which the positive type photoresist composition is coated onto a surface of the electroconductive layer to form a positive type photoresist film,

a pre-baking process in which the positive type photoresist film is heated,

an exposing process in which the resist film obtained by the pre-baking process is exposed, in a manner that at least part of a surface of the resist film disposed on the surface of the electroconductive layer is kept unexposed,

a developing process in which the exposed portion obtained by the exposing process is removed with the developer to uncover an electroconductive layer,

an electroconductive layer portion removing process in which the uncovered electroconductive layer portion is removed, and

a resist film portion removing process in which the remaining resist film portion is removed.

3. The method for forming a pattern of an electroconductive polymer according to 1 or 2 above, wherein the positive type photoresist composition contains the naphthoquinone diazide compound, the novolak resin, and a polyvinyl methyl ether.
4. The method for forming a pattern of an electroconductive polymer according to 3 above, wherein a calculational value E (° C.) is in the range from 60° C. to 110° C., the calculational value is calculated by the following equation (1) based on a softening point A (° C.) of the novolak resin and a content B (parts by weight) of the novolak resin, and a glass transition temperature C (° C.) of the polyvinyl methyl ether and a content D (parts by weight) of the polyvinyl methyl ether:

B/{100×(273+A)}+D/{100×(273+C)}=1/(273+E) (1)

(in the equation, B+D=100).

5. The method for forming a pattern of an electroconductive polymer according to any one of 1 to 4 above, wherein the electroconductive polymer is a polythiophene or a polypyrrole.
6. The method for forming a pattern of an electroconductive polymer according to 5 above, wherein the polythiophene is a poly(3,4-ethylenedioxythiophene).
7. The method for forming a pattern of an electroconductive polymer according to any one of 1 to 6 above, wherein the developer contains at least one compound selected from the group consisting of a polyoxyethylene alkylether and a halogenide of an alkaline earth metal.
8. The method for forming a pattern of an electroconductive polymer according to any one of 1 to 7 above, wherein the composition for forming an electroconductive layer contains a solvent having a boiling point of 100° C. or higher at an atmospheric pressure.
9. A plate having a pattern of an electroconductive polymer characterized in that the plate is obtained utilizing the method for forming a pattern of an electroconductive polymer according to any one of 1 to 8 above.

### Effect of the Invention

According to the present invention, a fine pattern of an electroconductive polymer can be efficiently formed which has electroconductive and is excellent in flexibility.

### BRIEF DESCRIPTION OF THE DRAWINGS

FIG. 1 is a schematic cross-sectional view of a pattern of electroconductive polymer disposed on a surface of a base body;

FIG. 2 is a schematic cross-sectional view of a laminated state after the film forming process in the present method;

FIG. 3 is a schematic cross-sectional view of a patterned resist layer portion on an electroconductive layer after the developing process in the present method; and

FIG. 4 is a schematic cross-sectional view of a patterned laminated portion after the electroconductive layer removing process in the present method.

### EXPLANATION OF THE REFERENCE NUMBERS

11: base body, 12: electroconductive layer, 121: patterned electroconductive layer portion, 13: positive type photoresist coating film, 131: patterned resist layer portion.

### Embodiments for Carrying Out the Invention

Hereinafter, the present invention is described in detail. In the present specification, “%” means % by weight.

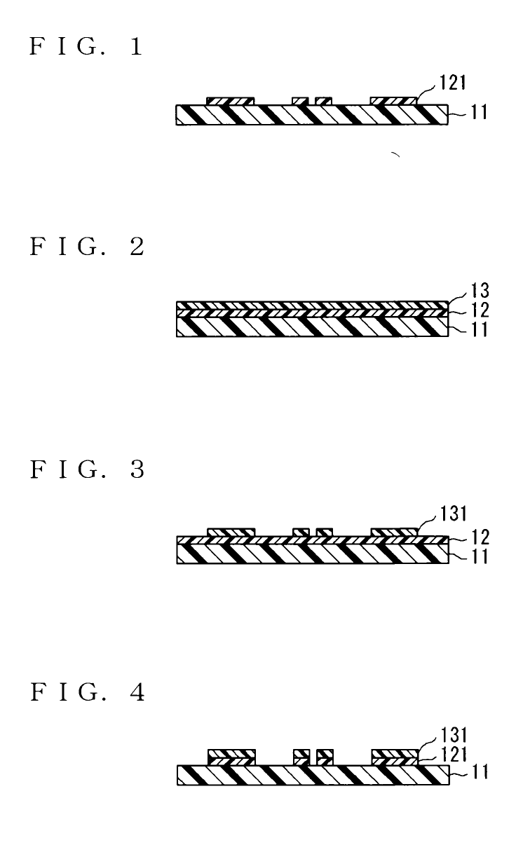

The present invention is a method for forming a pattern of an electroconductive polymer and a method for the formation of a patterned electroconductive layer portion 121 having a predetermined shape provided on a base body 11, as shown in FIG. 1. Hereinafter, the “pattern of an electroconductive polymer” is referred to as “electroconductive pattern”.

In the present invention, a method including an electroconductive layer forming process in which a composition for forming an electroconductive layer containing an electroconductive polymer is used to form an electroconductive layer on a surface of a base body, a film forming process in which the positive type photoresist composition is coated onto a surface of the electroconductive layer to form a film, a pre-baking process in which the film is heated, an exposing process in which the resist film obtained by the pre-baking process is exposed, in a manner that at least part of a surface of the resist film disposed on the surface of the electroconductive layer is kept unexposed, a developing process in which the exposed portion obtained by the exposing process is removed with the developer to uncover at least part of a surface of the electroconductive layer, an electroconductive layer portion removing process in which the uncovered electroconductive layer portion is removed, and a resist film portion removing process in which the remaining resist film portion is removed, leads to a formation of an electroconductive pattern. The positive type photoresist composition is a composition containing a naphthoquinone diazide compound and a novolak resin, and the developer is a liquid containing a potassium ion at a concentration of 0.08 mol/l to 0.20 mol/l, and a coexistent sodium ion at a concentration of less than 0.1 mol/l.

In the positive type photoresist composition, two components of the naphthoquinone diazide compound and the novolak resin are essential, and the composition usually contains a solvent to be described later. Further, this composition may contain a polyvinyl methyl ether, and may contain, as necessary, an additive such as a dye, an adhesive adjuvant, and a surfactant, which are to be used combinedly with a positive type photoresist. In the case where the positive type photoresist composition contains an additive, the content ratio of the aforementioned indispensable two components or the main three components additionally including the polyvinyl methyl ether, is preferably 70% or more, and more preferably 80% or more relative to the whole of the composition. Particularly, when the positive type photoresist composition contains the naphthoquinone diazide compound, novolak resin and polyvinyl methyl ether, larger content ratio of the polyvinyl methyl ether leads to a flexibility defined by the equation (1) to be more readily exhibited, without affection of an additive, being preferable.

The naphthoquinone diazide compound is a photosensitive component of a positive type photoresist, and an example thereof includes 1,2-naphthoquinonediazide-5-sulfonic acid; an ester or amide of 1,2-naphthoquinonediazide-5-sulfonic acid or 1,2-naphthoquinonediazide-4-sulfonic acid.

Among these, 1,2-naphthoquinonediazide-5-sulfonic acid ester and 1,2-naphthoquinonediazide-4-sulfonic acid ester of a polyhydroxy aromatic compound are preferable. And 1,2-naphthoquinonediazide-5-sulfonic acid ester and 1,2-naphthoquinonediazide-4-sulfonic acid ester of a polyhydroxy such as 2,3,4-trihydroxybenzophenone, 2,3,4,4′-tetrahydroxybenzophenone, 2,2′,4,4′-tetrahydroxybenzophenon and 2,3,4,2′,4′-pentahydroxybenzophenone are more preferable.

The novolak resin is a film-forming component of a positive type photoresist. The novolak resin is not particularly limited and may be one as a film-forming substance which is typically used in conventionally known positive type resist compositions, such as a substance to be exemplarily obtained by condensation of an aromatic hydroxy compound such as phenol, cresol and xylenol, and an aldehyde such as formaldehyde in the presence of an acid catalyst such as oxalic acid and p-toluenesulfonic acid.

Regarding the content ratio of the novolak resin and the naphthoquinone diazide compound in the resist composition, the content of the naphthoquinone diazide compound is in the range from 5 to 100 parts by weight, and more preferably from 10 to 80 parts by weight based on 100 parts by weight of the novolak resin. If the content of the naphthoquinone diazide compound is less than 10 parts by weight, a residual film ratio and resolution are deteriorated. On the other hand, if the content thereof exceeds 70 parts by weight, sensitivity is deteriorated.

The molecular weight of the polyvinyl methyl ether is not particularly limited and the polyvinyl methyl ether may be a polymer in all lengths. Examples of the polyvinyl methyl ether include a commercially product such as “Lutnal M40” and “Lutnal A25” manufactured by BASF, and the like. The polyvinyl methyl ether typically has a Tg of −31° C. When the polyvinyl methyl ether is formulated into a positive type photoresist composition containing a hard and brittle novolak resin as an essential component, a resist film after film formation is allowed to possess flexibility. In the case where the positive type photoresist composition contains a polyvinyl methyl ether, the amount of the polyvinyl methyl ether to be added is determined such that a calculational value E (° C.) in the following equation (1) satisfies a temperature of preferably 60° C. to 110° C., and more preferably 70° C. to 100° C. In the following equation (1), A denotes a softening point (° C.) of the novolak resin, and B denotes a content (parts by weight) thereof. Further, C denotes a glass transition temperature (° C.) of the polyvinyl methyl ether, and D denotes a content (parts by weight) thereof:

B/{100×(273+A)}+D/{100×(273+C)}=1/(273+E) (1)

(in the equation, B+D=100).

It is noted that the equation (1) is usually based on the following equation (2) which is known in the name of “Fox equation”. This equation (2) has been known from long ago in a literature (T. G. Fox, Bull. Am. Physics Soc., Volume 1, Issue No. 3, page 123 (1956)), and is known as an equation capable of calculationally obtaining a glass transition temperature (Tg (calculational value)) of a copolymer from actually measured values of compositional weights w of a monomer M1 and a monomer M2, and glass transition temperatures Tg of homopolymers obtained by using each of the monomers, respectively:

1/Tg(calculational value)=w(M1)/Tg(M1)+w(M2)/Tg(M2) (2)

In the present invention, a softening point A of the novolak resin can be determined by a ring and ball method (B & R method) prescribed by JIS K2531-1960, for example. The reason why the softening point A of the novolak resin is substitutionally used instead of the Tg value in the original Fox equation (2), is that the application of the equation (2) is difficult because a novolak resin typically fails to exhibit a definite Tg value.

The glass transition temperature C of the polyvinyl methyl ether can be determined by utsing DSC according to a method prescribed in JIS K7121-1967, for example. It is possible to adopt therefor a value defined as a midpoint glass transition temperature Tmg. Since a literature value of −31° C. is shown as a glass transition temperature of polyvinyl methyl ether in many known literatures to be enumerated below, it is sufficient in the present invention to substitutionally adopt the value of “−31° C.”, instead of an actually measured value, as the value of the glass transition temperature C of the polyvinyl methyl ether in the equation (1).

Examples of the literatures describing −31° C. as a glass transition temperature of the polyvinyl methyl ether exemplarily include: page 1,276 of “Polymer Material Handbook (first edition)” (1973) edited by The Society of Polymer Science, Japan, and published by CORONA PUBLISHING Co., Ltd.; page 528 of “Polymer Data Handbook (FIRST EDITION)” (1986) edited by The Society of Polymer Science, Japan, and published by BAIFUKAN CO., LTD.; VI/215 page of “POLYMER HANDBOOK (FOURTH EDITION)” (1999) published by JOHN WILEY & SONS, INC.; and the like.

It has been conventionally considered that application of the Fox equation is impossible, to a resin of which Tg is not measurable. Nonetheless, the present inventors have substitutionally used a softening point A of the novolak resin instead of its Tg such that the obtained calculational value E exhibited a close correlation with a bending resistance of a resist film obtained using the positive type photoresist composition, thereby finding out that such a calculational value is effective in formulating a positive type photoresist composition which is not leading to a crack, peeling, and the like when the positive type photoresist composition is used for a flexible substrate or a flexible electroconductive polymer.

According to the equation (1), a lower softening point of a novolak resin which is contained in the positive type photoresist composition results in smaller calculational values E, so that the flexibility of the resultant resist film is improved. In addition, since Tg of the polyvinyl methyl ether is typically as low as −31° C., when a novolak resin having the same softening point is used, a higher content D of the polyvinyl methyl ether or a lower content B of the novolak resin results in smaller calculational values E, thereby improving flexibility of a resist film to be obtained.

If the calculational value E is less than 60° C., tackiness of the resist film formed on an electroconductive layer may be increased, resolution may be deteriorated due to swelling or the like upon development, and underdevelopment may be caused easily. On the other hand, if the calculational value E exceeds 110° C., flexibility of the resist film formed on the electroconductive layer may be considerably reduced, and a crack or peeling may be caused easily due to bending upon transportation, handling, or the like to thereby break an electroconductive pattern.

In the case where the positive type photoresist composition contains a polyvinyl methyl ether, the content thereof is preferably in the range from 1 to 100 parts by weight, and more preferably from 2 to 70 parts by weight based on 100 parts by weight of the novolak resin.

As described above, the positive type photoresist composition may contain a solvent. Examples of the solvent include an alkyleneglycol mono alkyl ether, an alkyleneglycol mono alkyl ether acetate, a lactate, a carbonate, an aromatic hydrocarbon, a ketone, an amide, a lactone, and the like. The solvent may be used singly or in combination of two or more types thereof. The amount of the solvent to be used is not particularly limited and it is preferable to adopt the amount of the solvent such that the total concentration of the naphthoquinone diazide compound, the novolak resin, and the like is within a range of 3% to 30%.

In the present invention, the electroconductive pattern is formed by a method preferably including an electroconductive layer forming process, a film forming process, a pre-baking process, an exposing process, a developing process, an electroconductive layer portion removing process, and a resist film portion removing process, sequentially.

The electroconductive layer forming process is a process in which a composition for forming an electroconductive layer containing an electroconductive polymer is used to form an electroconductive layer on a surface of a base body.

The base body is not particularly limited, insofar as the base body does not cause deformation, alteration, and the like in the pre-baking process, developing process, and the like. The base body is usually made of a material containing a resin, a metal, an inorganic compound and the like. Examples of the base body include a film, a sheet, a plate and the like that contain a resin; a foil, a plate and the like that contain a metal, an inorganic compound or the like. In the present invention, the base body is preferably a film and a film containing a thermoplastic resin such as a polyester resin including polyethylene terephthalate, a polyester resin including polyethylene terephthalate and polyethylene naphthalate, a polysulphone resin, a polyether sulphone resin, a polyether ketone resin, and a cycloolefin resin is particularly preferred.

Examples of the electroconductive polymer which is contained in the composition for forming an electroconductive layer include a polythiophene, a polypyrrole, and the like. These polymers may be used singly or in combination of two or more types thereof. Preferable electroconductive polymer is a polythiophene having a higher stability. Among the polythiophene, a poly(3,4-ethylenedioxythiophene) is particularly preferred which is excellent in electroconductivity, stability in air, and heat resistance.

The composition for forming an electroconductive layer may contain a dopant, an enhancer, and the like, for the purpose of improving electroconductivity of the electroconductive layer.

Examples of the dopant include conventionally known ones such as a halogen such as iodine and chlorine; a Lewis acid such as BF₃ and PF₅; a proton acid such as nitric acid and sulfuric acid; a transition metal; an alkali metal; an amino acid; a nucleic acid; a surfactant; a pigment; chloranil; tetracyanoethylene; TCNQ; and the like. In the case where a polythiophene is used as the electroconductive polymer, a polystyrene sulfonic acid is preferably used as a dopant.

When the composition for forming an electroconductive layer contains a dopant, the content thereof is preferably in the range from 50 to 5,000 parts by weight, more preferably from 100 to 3,000 parts by weight based on 100 parts by weight of the electroconductive polymer. When the dopant is contained in the amount within the above range, an improving effect of electroconductivity can be sufficiently obtained.

Further, the enhancer is a component for orderly arranging molecules of the electroconductive polymer upon formation of the electroconductive layer to thereby improve electroconductivity, and is preferably a polar compound having a boiling point of 100° C. or higher at an atmospheric pressure. Example thereof includes dimethyl sulfoxide (DMSO), N-methylpyrrolidone (NMP), dimethylformamide, dimethylacetamide, ethyleneglycol, glycerol, sorbitol, and the like. The enhancer may be used singly or in combination of two or more types thereof. When the composition for forming an electroconductive layer contains an enhancer, the content thereof is preferably in the range from 1% to 10%, and more preferably from 3% to 5% relative to the composition.

Commercially products may used as the composition for forming an electroconductive layer. Examples of a composition containing a polythiophene include products “CLEVIOS” (Registered Trade-Mark), such as “CLEVIOS P”, “CLEVIOS PH”, “CLEVIOS PH500”, “CLEVIOS P AG”, “CLEVIOS P HCV4”, “CLEVIOS FE”, and “CLEVIOS F HC” that are manufactured by H. C. Starck GmbH.

In addition, a product “CURRENFINE” (Registered Trade-Mark) can be used which is manufactured by Teijin DuPont Films Japan Limited. This product contains a poly(3,4-ethylenedioxythiophene), and a polystyrene sulfonic acid as a dopant.

In the electroconductive layer forming process, the forming method of the electroconductive layer is not particularly limited. For example, when the composition for forming an electroconductive layer is coated on a base body and dried, a composite body can be obtained in which an electroconductive layer (electroconductive film) is adhered to a surface of the base body. The coating method of the composition for forming an electroconductive layer is not particularly limited and example thereof includes a spin coating method, a roll coating method, a dipping method, a casting method, a spraying method, an ink jetting method, a screen printing method, an applicator method, and the like. The coating condition is selected, in consideration of the coating method, a solid content concentration of the composition, a viscosity of the composition, and the like, so as to achieve a desired thickness.

Further, example of the other method for forming the electroconductive layer includes a method in which the composition for forming an electroconductive layer is coated on a base material from which the film is peelable after formation thereof, and dried to obtain an electroconductive film, and then the electroconductive film is adhered to a surface of a base body to thereby form a composite. At this time, it is possible to use an adhesive, or to utilize heating or the like without utilizing an adhesive. It is noted that the electroconductive layer may be formed over the whole surface of the base body, or may be formed on a desired portion of the base body.

The thickness of the electroconductive layer (electroconductive film) is preferably in the range from 0.01 to 10 μm, and more preferably from 0.03 to 1 μm.

It is possible to use a laminate in which an electroconductive layer containing an electroconductive polymer is previously formed on a surface of a base body. For example, a film laminate comprising a resin film, and an electroconductive layer formed on a surface of the resin film can be used. Examples of the film laminate include “ST-8” of “ST-PET sheet” manufactured by Achilles Corp. which has an electroconductive layer containing a polypyrrole.

The film forming process is a process in which the positive type photoresist composition is coated onto a surface of the electroconductive layer 12, to form a film (positive type photoresist coating film) 13 (see, FIG. 2). Coating method of the composition is not particularly limited and a spin coating method, a roll coating method, a dipping method, a casting method, a spraying method, an ink jetting method, a screen printing method, an applicator method, and the like can be used. Although the composition is typically coated at a room temperature, it is possible to coat the composition while heating the electroconductive layer, as required.

The thickness of the film (positive type photoresist coating film) obtained by the film forming process is preferably in the range from 0.5 to 10 μm, and more preferably from 1 to 5 μm.

FIG. 2 shows a laminated state after the film forming process, and is a schematic cross-sectional view of a laminate comprising the base body 11, electroconductive layer 12, and positive type photoresist coating film 13, successively.

Thereafter, the film (positive type photoresist coating film) is heated in the pre-baking process, thereby forming a resist film (dried film). Although the heating condition in this process is appropriately selected depending on the formulation of the positive type resist composition, the preferable heating temperature is in the range from 80° C. to 140° C. The environment upon heating is not particularly limited and is usually an atmospheric air.

The thickness of the resist film obtained in the pre-baking process is preferably in the range from 0.5 to 10 μm, and more preferably from 1 to 5 μm. When the thickness is in the above range, deterioration of yield due to pinholes is restricted, treatments including exposure, development, stripping and the like can be finished within short times, and development failure and stripping failure are rarely caused, being favorable.

Subsequently, light is selectively irradiated onto the resist film (exposing process). In the exposing process, at least part (a resist film portion on a surface of a patterned electroconductive layer portion 121 to be formed later) of a surface of the resist film arranged on the surface of the electroconductive layer 12 is kept unexposed. Namely, radiation is irradiated onto the surface of the resist film through a photomask having patterned openings so that a patterned resist layer portion 131 is left on the surface of the electroconductive layer 12 after a developing process. This causes the radiation to pass through the openings of the photomask and then through a lens for exposure, to arrive at the resist film. Those exposed portions of the resist film possess solubility in alkali, so that they are removed in the developing process.

The exposure conditions in the exposing process are appropriately selected depending on a composition (type of additives, and the like), thickness, and the like of the resist film. Further, examples of the radiation used for the exposure include visible light, ultraviolet rays, far ultraviolet rays, X-rays, charged particle radiation such as electron beam, and the like.

After that, the exposed portions are removed by means of a developer in the developing process, thereby uncovering a surface of the electroconductive layer (see, FIG. 3). FIG. 3 is a schematic cross-sectional view showing that a remaining patterned resist layer portion 131 is formed on the electroconductive layer 12 by removal of the exposed portions in the developing process. Since the resist composition used in the film forming process typically forms an electrically insulative material, the resist layer portion 131 is capable of acting as an electrically insulative resin portion.

The developer for the naphthoquinone diazide-novolak type photoresist is generally an alkaline aqueous solution. Examples of alkali used for preparing the alkaline aqueous solution include an organic alkali and an inorganic alkali. For manufacturing of electric/electronic parts including semiconductors, liquid crystal panels, printed circuit boards, and the like, an organic alkali including tetraalkylammonium hydroxide such as tetramethylammonium hydroxide (hereinafter, abbreviated to “TMAH”) is frequently used. On the other hand, in the case where a target of etching is a metal such as copper and chromium, sodium hydroxide, a buffering solution consisting of sodium hydroxide and an inorganic alkali such as sodium carbonate, or the like is sometimes used.

The present inventors have found out that: when a positive type photoresist coating film 13 was formed on an electroconductive layer 12 containing an electroconductive polymer, and after exposure, the resist film was developed using an alkaline aqueous solution as a developer containing a potassium ion at a predetermined concentration, which developer has been prepared using potassium hydroxide, it was enabled to freely and preferably form a patterned resist layer portion (resist pattern) ranging from narrow to thick in line width, such that the removal of the uncovered electroconductive layer portion by etching or the like and the stripping of the remaining resist layer portion 131 subsequent to the developing process, could be effectively progressed without deteriorating the shape of the electroconductive layer, thereby forming a pattern of the electroconductive polymer.

It is known that an aqueous solution of potassium hydroxide is typically stronger in alkalinity and stronger in corrosivity than an aqueous solution of sodium hydroxide. However, it has been revealed that a developer containing a potassium ion at a predetermined concentration is milder in action on a resist film, than a developer containing a sodium ion in a large amount.

In the case of using an alkaline aqueous solution containing TMAH as an organic alkali, or an alkaline aqueous solution containing only sodium hydroxide among an inorganic alkali, was used, those patterns ranging from narrow to thick in line width, which are to be left, were peeled off and separated from an electroconductive layer at the time of completion of a developing process or shortly thereafter, thereby making it difficult to form a desired resist pattern.

Contrary, it was possible to satisfactorily form patterns ranging from narrow to thick in line width, in the case of using an alkaline aqueous solution containing at least potassium ion. The concentration of the potassium ion at this time is in the range from 0.08 mol/l to 0.20 mol/l, preferably from 0.09 mol/l to 0.18 mol/l, and more preferably 0.09 mol/l to 0.15 mol/1.

When the concentrations of the potassium ion in the developer is within the above range, underdevelopment rarely causes even if a developing treatment is performed for a short time, and a resist pattern become hard to be peeled off and separated from the electroconductive layer. Therefore, a desired resist pattern can be formed within this range of the concentration.

Examples of the alkali metal ion other than potassium ion for the developer include a sodium ion, lithium ion, rubidium ion, cesium ios, and the like. Particularly, a sodium ion, even when coexistent with a potassium ion, efficiently leads to a removal of exposed portions of a resist layer after the exposing process, thereby enabling to implement the present invention. However, when the concentration of the sodium ion is too high, a resist pattern is easily peeled off and separated from the electroconductive layer, thereby making it difficult to form a desired resist pattern. Thus, the upper limit of the concentration of the sodium ion in the developer is less than 0.1 mol/l.

The pH of the developer is preferably pH12 or more, and more preferably pH13 or more. The upper limit thereof is pH14, which is typically defined as an upper limit of pH.

When the alkaline aqueous solution has absorbed thereinto carbon dioxide in the air, developing capability is deteriorated. As such, it is possible to add an appropriate amount of a carbonate in addition to a potassium ion or the like, to thereby prepare a buffering solution so as to restrict deterioration of the developing capability, and to use it as a developer. Examples of the carbonate include sodium carbonate, potassium carbonate and the like. In the case of adopting a potassium carbonate, its amount is preferably about 1.0 to 1.3 times the weight of potassium hydroxide. In the case of adopting a sodium carbonate, its amount is preferably less than 0.1 mol/l when calculated as a sodium ion concentration.

In the present invention, after the exposed portions of the resist layer are removed by development, the surface of the uncovered electroconductive layer portion is caused to contact with a developer. The development time is preferably in the range from 1 second to 30 minutes, and more preferably from 10 seconds to 200 seconds. If the development time is too long, part of a surface of the electroconductive layer may be removed. In turn, if the development time is too short, underdevelopment may be caused. The electroconductive layer portion, which is uncovered by the developing process, is removed by the electroconductive layer portion removing process. In the case where the electroconductive layer portion is not etched, the same is utilizable as a switch or the like by using the resist pattern. Namely, there is such a possibility that the electroconductive layer portion after contact with a developer is used, and in such a case, it is preferable that the electroconductivity of the electroconductive film layer portion is not deteriorated by contact with the developer.

The developer used in the method for forming an electroconductive polymer of the present invention is characterized in that the electroconductive layer portion is not deteriorated in electroconductivity, even by contact with the developer. Moreover, when a protective agent is added into the developer, deterioration of an electroconductivity of the electroconductive film layer can be further restricted upon contact with the developer. Examples of the protective agent include a surfactant, an inorganic salt, a carboxylate, an amino acid, and the like. Among these, a surfactant, an inorganic salt and an amino acid are preferable. The surfactant is preferably a nonionic surfactant, and the inorganic salt is preferably a neutral calcium salt. More specifically, preferable as the surfactant is a polyoxyethylene alkyl ether, and polyoxyethylene tridecyl ether is particularly preferred. Particularly preferable as the inorganic salt is a halogenide of an alkaline earth metal, such as calcium chloride. Further, preferable as the amino acid is an α-amino acid such as glycine, and the α-amino acid as a constituent component of a protein is particularly preferred. The content of the protective agent is not particularly limited and the lower limit of the content is preferably 0.001%, and more preferably 0.01% relative to the whole of the developer. Although a higher containment ratio of this protective agent further improves its effect, the upper limit is generally 5%, and is preferably 3%.

In the developing process, the temperature of the developer is not particularly limited. Higher temperature of the developer leads to a faster development rate. In turn, although lower temperature leads to a slower development rate and necessitates longer times, film decrease, resist pattern separation, and the like are rarely caused then. Thus, the preferable temperature of the developer is in the range from 15° C. to 35° C.

Usable as a developing method is a method such as an immersing method, spraying method, or the like.

After obtaining the structure shown in FIG. 3 by the developing process, the uncovered electroconductive layer portion is removed by the electroconductive layer portion removing process (see, FIG. 4). FIG. 4 is a schematic cross-sectional view showing that the electroconductive layer portion is removed. Further, this figure shows a configuration comprising a base body 11, a patterned electroconductive layer portion 121 which is arranged on the surface of the base body 11 and has a predetermined shape, and a patterned resist layer portion 131 which is arranged to cover the surface of the patterned electroconductive layer portion 121.

When the uncovered electroconductive layer portion is removed, known etching solutions and known etching methods can be utilized in accordance with a nature of the electroconductive polymer. Specific examples of an etching liquid include an etching liquid containing (NH₄)₂Ce(NO₃)₆ in an amount of no less than 0.5% and 70% or less, and an etching liquid containing Ce(SO₄)₂ in an amount of 0.5% to 30%, that are described in International Publication Pamphlet WO 2008/041461. Specific examples of an etching method are the same as those described in the above International Publication Pamphlet.

In the present invention, when an etching liquid containing (NH₄)₂Ce(NO₃)₆ in an amount of preferably 1% to 30%, and more preferably 3% to 20% is used, an uncovered electroconductive layer portion can be efficiently removed without damaging an electroconductive layer under the patterned resist layer portion 131.

After that, the remaining resist film portion, i.e., the patterned resist layer portion 131 remaining on the surface of the patterned electroconductive layer portion 121, is removed by the resist film portion removing process to complete the pattern formation of the electroconductive polymer according to the present invention.

The method for removing the patterned resist layer portion 131 is as follows. Examples of a stripping agent usable in the present invention include an aprotic organic solvent (a) having a chemical structure containing an oxygen atom, or a sulfur atom, or both therein; and an organic solvent (b) other than a primary amine compound, a secondary amine compound, and an organic quarternary ammonium salt, the organic solvent (b) having a chemical structure containing a nitrogen atom therein. The aprotic organic solvent (a) and organic solvent (b) may be used in combination.

Examples of the aprotic organic solvent (a) include a dialkyl sulfoxide such as dimethylsulfoxide and diethyl sulfoxide; a dialkyl sulfone such as sulfolane and dimethyl sulfone; an alkylene carbonate such as ethylene carbonate and propylene carbonate; an alkylolactone such as ε-caprolactam, γ-butyrolactone, δ-valerolactone, and ε-caprolactone; acetonitrile; an ether such as diglyme and triglyme; dimethoxyethane; and the like. The compound may be used singly or in combination of two or more types thereof.

Among them, a dialkyl sulfoxide, alkylene carbonate and alkylolactone are preferable from the viewpoints that they are relatively low in boiling point, excellent in drying property, high in safety, and easy to handle. Dimethylsulfoxide, ethylene carbonate, propylene carbonate and γ-butyrolactone are more preferable. Dimethylsulfoxide, ethylene carbonate and γ-butyrolactone are particularly preferred.

Examples of the organic solvent (b) include an N-alkylpyrrolidone such as N-methylpyrrolidone and N-vinylpyrrolidone; a dialkylcarboamide such as N,N-dimethylformamide, N,N-dimethylacetoamide, and N,N-diethylacetoamide; 1,3-dimethyl-2-imidazoline; tetramethylurea; triamide hexamethyl phosphate; and the like. The compound may be used singly or in combination of two or more types thereof.

Among them, an N-alkylpyrrolidone and dialkylcarboamide are preferable from the viewpoints that they are easy to handle and high in safety. N-methylpyrrolidone, dimethylformamide and dimethylacetoamide are particularly preferred.

In the present invention, it is particularly preferable to use a mixture of the aprotic organic solvent (a) and organic solvent (b). When the mixture is used, the patterned resist layer portion 131 is more excellent in stripping ability than the patterned electroconductive layer portion 121, and the usage does not increase a surface resistance of the patterned electroconductive layer portion 121 after stripping, i.e., the usage does not lower an electroconductivity thereof, nor lower an adherence between the base body 11 and the patterned electroconductive layer portion 121, being preferable.

In the case where the aprotic organic solvent (a) and organic solvent (b) are used, the mixing ratio thereof is preferably (a)/(b)=99 to 10/1 to 90 (weight ratio), and more preferably (a)/(b)=70 to 20/30 to 80 (weight ratio).

In addition to the aprotic organic solvent (a) and organic solvent (b), it is possible to add other compound into the stripping agent usable in the present invention, to the extent that the stripping property thereof is not deteriorated. Examples of the other compound include an alcohol such as methanol, ethanol, ethyleneglycol and glycerol; an alkylene glycol such as polyethyleneglycol, polypropyleneglycol and polytetramethyleneglycol; a glycol ether such as ethyleneglycol mono methyl ether, ethyleneglycol mono ethyl ether and ethyleneglycol mono butyl ether; water, and the like.

The treating temperature in the resist film portion removing process is not particularly limited. Higher treating temperature tends to decrease the viscosity of the stripping agent, thereby finishing removal of the resist film portion in a short time. However, excessively higher treating temperature occasionally increases a surface resistance of the patterned electroconductive layer portion 121 after removing of the resist film portion, thereby lowering an electroconductivity thereof. Therefore, the temperature is preferably in the range from 5° C. to 60° C., more preferably from 5° C. to 50° C., and particularly from 10° C. to 40° C.

According to the present invention, it is possible to efficiently form a finely patterned electroconductive layer excellent in flexibility and electroconductivity. According to the present invention, the line width of the electroconductive layer can be, for example, in the range from 5 μm to 1 mm. According to the present invention, the electrical conductivity can be, for example, in the range from 15 to 1,000 S/cm.

### EXAMPLE

Hereinafter, the present invention is specifically described using Examples. The present invention is not limited to these Examples.

### 1. Positive Type Photoresist Composition

### 1-1. Naphthoquinone Diazide Compound

In the presence of triethylamine, 2,3,4-trihydroxybenzophenone was subjected to condensation reaction with naphthoquinone diazide-5-sulfonylchloride in an amount of three times the molar amount of the former, thereby obtaining a yellowish solid sulfonate (hereinafter, referred to as “NQD”). Analyzing it with a high-speed liquid chromatography showed that peak areas of triesters were 95% or more of the whole peak area.

The measurement for the high-speed liquid chromatography was conducted by using an apparatus (“GULLIVER 900 SERIES” manufactured by JASCO Corp.) with a column “Inertsil ODS-3” (4.6 mm ID×150 mm) manufactured by GL Sciences Inc., an UV detector (wavelength 254 nm) as a detector, and by flowing a carrier solvent comprising water/acetonitrile/triethylamine/phosphoric acid=68.6/30.0/0.7/0.7 at a volume ratio, and at a flow rate of 1.0 ml/minute.

### 1-2. Novolak Resin

### (1) Cresol Novolak Resin

Used was a cresol novolak resin (trade name “MER7969” manufactured by MEIWA PLASTIC INDUSTRIES, LTD.) obtained by condensation of m-cresol and p-cresol by means of formaldehyde. The softening point is 145° C.

### (2) Cresol Novolak Resin

Used was a cresol novolak resin (trade name “Phenolite KA-1053” manufactured by DIC Corp.). The softening point is 164° C.

### 1-3. Polyvinyl Methyl Ether (PVM)

Used was a polyvinyl methyl ether (trade name “Lutnal M-40” manufactured by BASF). The glass transition temperature is −31° C.

### 1-4. Preparation of Positive Type Photoresist Composition

Positive type photoresist compositions (C-1 and C-7) were obtained, each by adding 20 parts by weight of NQD into 160 parts by weight (i.e., 80 parts by weight as a solid content) of propyleneglycol mono methyl ether acetate solution of cresol novolak resin (solid content concentration of 50%). Further, positive type photoresist compositions (C-2 to C-6, and C-8 to C-12) were obtained, each by further adding propyleneglycol mono methyl ether acetate solution of polyvinyl methyl ether (PVM) in accordance with Table 1 and Table 2, as required. Propyleneglycol mono methyl ether acetate was appropriately added as a diluting solvent into each composition and homogeneously dissolved therein so that the solid content concentration of the whole of the composition was made to be 20%. Shown in Table 1 and Table 2 are calculational values E each obtained by the equation (1) based on the addition amounts of the applicable novolak resin and PVM.

### 2. Evaluation of Bending Resistance for Resist Film

Coated onto a polyethylene terephthalate film (thickness 200 μm) having a corona treated surface, was a composition (trade name “CLEVIOS PH500” manufactured by H. C. Starck GmbH) for forming an electroconductive layer containing poly(3,4-ethylenedioxythiophene), followed by drying, to form an electroconductive film having a thickness of 500 nm. Subsequently, each positive photoresist composition obtained in the above was coated onto the surface of the electroconductive film by a spin coater and was subjected to pre-baking at a temperature of 100° C. for 10 minutes to form a resist film having a thickness of 3 μm, thereby obtaining a film laminate. Using each film laminate, the bending resistance of the resist film was evaluated according to JIS K5600-5-1. The results are shown in Table 1 and Table 2. Bending resistance R indicates a minimum diameter (mm) of the applicable resist film where no cracks were caused in the resist film when the film laminate was bent at angles of 90 degree and 180 degree, respectively.

TABLE 1

| | | Starting material | | | | Evaluation | |
|---|---|---|---|---|---|---|---|
| | | MER7969 | NQD | PVM | E calculated | Bending resistance | |
| | | (Parts by | (Parts by | (Parts by | by equation | R (mm) | |
| | | weight) | weight) | weight) | (1) (° C.) | 90 deg. | 180 deg. |
| Resist | C-1 | 80 | 20 | 0 | 146 | >10 | >10 |
| composition | C-2 | 80 | 20 | 10 | 115 | 10 | >10 |
| | C-3 | 80 | 20 | 20 | 93 | 4 | 8 |
| | C-4 | 80 | 20 | 30 | 76 | 3 | 8 |
| | C-5 | 80 | 20 | 40 | 64 | 3 | 8 |
| | C-6 | 80 | 20 | 50 | 54 | 2 | 6 |

TABLE 2

| | | Starting material | | | | Evaluation | |
|---|---|---|---|---|---|---|---|
| | | KA-1053 | NQD | PVM | E calculated | Bending resistance | |
| | | (Parts by | (Parts by | (Parts by | by equation | R (mm) | |
| | | weight) | weight) | weight) | (1) (° C.) | 90 deg. | 180 deg. |
| Resist | C-7 | 80 | 20 | 0 | 164 | >10 | >10 |
| composition | C-8 | 80 | 20 | 10 | 128 | >10 | >10 |
| | C-9 | 80 | 20 | 20 | 103 | 8 | 10 |
| | C-10 | 80 | 20 | 30 | 85 | 6 | 8 |
| | C-11 | 80 | 20 | 40 | 72 | 4 | 8 |
| | C-12 | 80 | 20 | 50 | 61 | 3 | 8 |

The film laminates obtained by using the positive type photoresist compositions C-3 to C-6 and C-9 to C-12 were favorable to exhibit bending resistances of 6 mm to 2 mm upon bending at 90 degree and of 8 mm or less upon bending at 180 degree, respectively. The evaluation was conducted in case of a thickness of 10 μm for each resist film as well, and the same result was shown as the thickness of 3 μm.

On the other hand, the film laminates obtained by using the positive type photoresist compositions C-1, C-2, C-7 and C-8 resulted in bending resistances of 10 mm, or excess of 10 mm upon bending at 90 degree, and of excess of 10 mm upon bending at 180 degree, respectively. These were inferior in bending resistance as compared to the cases where the positive type photoresist compositions C-3 to C-5, and C-9 to C-12 were exemplarily used.

### 3. Formation and Evaluation of Resist Pattern (I)

### Experimental Example 1

Coated onto a polyethylene terephthalate film (thickness 200 μm) having a corona treated surface, was a composition (trade name “CLEVIOS PH500” manufactured by H. C. Starck GmbH) for forming an electroconductive layer containing poly(3,4-ethylenedioxythiophene), followed by drying, to form an electroconductive film having a thickness of 500 nm. Subsequently, the positive photoresist composition C-4 was coated onto the surface of the electroconductive film by a spin coater and was subjected to pre-baking at a temperature of 100° C. for 10 minutes to form a resist film having a thickness of 1 μm, thereby obtaining a film laminate.

After that, the resist layer was exposed at an exposure dose of 100 mJ/cm² by using a mask aligner (type name “MA-10” manufactured by MIKASA CO., LTD.) having an ultra-high pressure mercury lamp as a light source, and through a photomask.

Subsequently, an aqueous alkali solution was used for development as a developer in which potassium hydroxide was dissolved at a concentration listed in Table 3 so as to solve out the exposed portion of the resist layer to thereby form a resist pattern comprising the residual resist layer. A thermostatic jacket was controlled to keep the temperature of the developer within a range of 23° C. to 25° C. Temperature measurement was conducted by a rod-like thermometer.

The resist pattern obtained at each development time was observed with a microscope, to examine a relationship between a developing property and the presence/absence of resist pattern separation. The results were shown in Table 3. In the upper entry of each applicable field in Table 3, the mark “X” indicates a case where underdevelopment was found considerably, the mark “Δ” indicates a case where underdevelopment was found slightly, and the mark “◯” indicates a case where underdevelopment was not found and the resist pattern was correctly formed. In turn, in the lower entry of each applicable field in Table 3, the mark “X” indicates a case where the resist pattern was peeled off and considerably separated irrespectively of a size of the resist pattern, the mark “Δ” indicates a case where separation of a resist pattern was found slightly, and the mark “◯” indicates a case where separation of a resist pattern was not found and the resist pattern was correctly formed. The entry of “-” indicates that the evaluation under the applicable condition was not conducted.

### Experimental Examples 2 to 5

Resist patterns were formed in the same manner as Experimental Example 1, except that developers having compositions listed in Table 3 were used, to obtain electroconductive patterns, respectively. Then, evaluation of developing property was conducted. The results were shown in Table 3. Potassium hydroxide was used in Experimental Example 3 and Experimental Example 4, and potassium hydroxide and sodium carbonate were used in Experimental Example 2. In Experimental Example 5, potassium hydroxide and potassium carbonate were used in a manner to achieve concentrations of potassium ion at 0.100 mol/l and 0.094 mol/l, respectively.

### Experimental Examples 6 to 9

Resist patterns were formed in the same manner as Experimental Example 1, except that a PET film (trade name “ST-PET sheet” manufactured by Achilles Corp.) with an electroconductive layer containing a polypyrrole was used instead of the composition (trade name “CLEVIOS PH500” manufactured by H. C. Starck GmbH) for forming an electroconductive layer containing poly(3,4-ethylenedioxythiophene). Then evaluation of developing property was conducted. The results were shown in Table 3.

### Experimental Examples 10 to 17

Resist patterns were formed in the same manner as Experimental Example 1, except that developers having compositions listed in Table 3 were used, to obtain electroconductive patterns, respectively. Then, evaluation of developing property was conducted. The results were shown in Table 3. Experimental Example 10 was an example in which potassium hydroxide was used, but the concentration of potassium ion was excessively low. Experimental Example 11 was an example where potassium hydroxide was used, but the concentration of potassium ion was excessively high. Experimental Examples 12 to 15 were examples where only sodium hydroxide was used. Experimental Example 16 was an example where sodium hydroxide and sodium carbonate were used combinedly so that the concentrations of sodium ion were made to be 0.100 mol/l and 0.094 mol/l by the former and latter, respectively. Experimental Example 17 was an example where sodium hydroxide and potassium carbonate were used combinedly.

### Experimental Examples 18 to 21

A resist pattern was formed in the same manner as in those in Experimental Example 1 except that an aqueous solution of TMAH that has potassium ion in an amount of zero and no metal was used as a developer. After that, the developability was evaluated. The result was shown in Table 4.

TABLE 3

| | Ion con- | | | | | | | | | |
|---|---|---|---|---|---|---|---|---|---|---|
| | centration | | | | | | | | | |
| | (mol/l) | | Development time (sec) | | | | | | | |
| | K⁺ | Na⁺ | 10 | 15 | 30 | 45 | 60 | 75 | 90 | 120 |
| Experimental | 0.089 | 0 | — | ◯ | ◯ | ◯ | ◯ | — | — | — |
| Example 1 | | | — | ◯ | ◯ | ◯ | ◯ | — | — | — |
| Experimental | 0.1 | 0.094 | — | — | ◯ | ◯ | ◯ | ◯ | ◯ | — |
| Example 2 | | | — | — | ◯ | ◯ | ◯ | Δ | Δ | — |
| Experimental | 0.125 | 0 | — | — | ◯ | ◯ | ◯ | ◯ | ◯ | ◯ |
| Example 3 | | | — | — | ◯ | ◯ | ◯ | ◯ | Δ | Δ |
| Experimental | 0.178 | 0 | — | ◯ | ◯ | ◯ | ◯ | ◯ | ◯ | ◯ |
| Example 4 | | | — | ◯ | ◯ | ◯ | ◯ | ◯ | ◯ | ◯ |
| Experimental | 0.194 | 0 | — | — | ◯ | ◯ | ◯ | ◯ | ◯ | — |
| Example 5 | | | — | — | ◯ | ◯ | ◯ | ◯ | ◯ | — |
| Experimental | 0.1 | 0.094 | — | — | ◯ | — | ◯ | — | — | ◯ |
| Example 6 | | | — | — | ◯ | — | ◯ | — | — | ◯ |
| Experimental | 0.125 | 0 | — | — | ◯ | — | ◯ | — | — | ◯ |
| Example 7 | | | — | — | ◯ | — | ◯ | — | — | ◯ |
| Experimental | 0.178 | 0 | — | — | ◯ | — | ◯ | — | — | ◯ |
| Example 8 | | | — | — | ◯ | — | ◯ | — | — | ◯ |
| Experimental | 0.194 | 0 | — | — | ◯ | — | ◯ | — | — | ◯ |
| Example 9 | | | — | — | ◯ | — | ◯ | — | — | ◯ |
| Experimental | 0.071 | 0 | — | X | Δ | Δ | Δ | — | — | — |
| Example 10 | | | — | — | — | — | — | — | — | — |
| Experimental | 0.357 | 0 | ◯ | ◯ | — | — | — | — | — | — |
| Example 11 | | | X | X | — | — | — | — | — | — |
| Experimental | 0 | 0.05 | — | — | — | — | X | X | X | X |
| Example 12 | | | — | — | — | — | — | — | — | — |
| Experimental | 0 | 0.075 | — | X | ◯ | — | — | — | — | — |
| Example 13 | | | — | — | X | — | — | — | — | — |
| Experimental | 0 | 0.089 | — | X | ◯ | — | — | — | — | — |
| Example 14 | | | — | — | X | — | — | — | — | — |
| Experimental | 0 | 0.125 | Δ | ◯ | — | — | — | — | — | — |
| Example 15 | | | — | X | — | — | — | — | — | — |
| Experimental | 0 | 0.194 | — | ◯ | ◯ | — | — | — | — | — |
| Example 16 | | | — | Δ | X | — | — | — | — | — |
| Experimental | 0.094 | 0.1 | — | ◯ | — | — | — | — | — | — |
| Example 17 | | | — | X | — | — | — | — | — | — |

TABLE 4

| | TMAH | | | | | | | | |
|---|---|---|---|---|---|---|---|---|---|
| | concentration | Development time (sec) | | | | | | | |
| | (% by weight) | 10 | 15 | 30 | 45 | 60 | 75 | 90 | 120 |
| Experimental | 0.75 | — | X | ◯ | — | — | — | — | — |
| Example 18 | | — | — | X | — | — | — | — | — |
| Experimental | 0.9 | — | ◯ | ◯ | — | ◯ | — | — | — |
| Example 19 | | — | ◯ | Δ | — | X | — | — | — |
| Experimental | 1 | — | ◯ | — | — | — | — | — | — |
| Example 20 | | — | X | — | — | — | — | — | — |
| Experimental | 1.5 | — | ◯ | — | — | — | — | — | — |
| Example 21 | | — | X | — | — | — | — | — | — |

Clearly from the results in Table 3, it is found that Experimental Examples 1 to 9, where the concentrations of potassium ion of the developers were made to be within the range of 0.08 mol/l to 0.20 mol/l and the concentrations of coexistent sodium ion were made to be less than 0.1 mol/l, respectively, exhibited longer ranges of developing time during which underdevelopment was less without separation of resist pattern, and thus were practical.

In addition, it was further shown that, those Experimental Examples, where the alkaline aqueous solution containing only sodium ion (Experimental Examples 12 to 16) or the aqueous solution of TMAH (Experimental Examples 18 to 21) was used, and where the potassium hydroxide aqueous solution was used but the concentration of potassium ion of the developer was out of the range of 0.08 mol/l to 0.20 mol/l, were not practical, because they were each insufficient in developing property, or because they were less in the number of fields of development time condition where “underdevelopment was not found, and separation of resist pattern was not found”, i.e., where both the upper and lower entries were evaluated to be “◯” in Table 3 and Table 4.

### 4. Formation and Evaluation of Resist Pattern (II)

### Experimental Examples 22 to 27

Coated onto a polyethylene terephthalate film (thickness 200 μm) having a corona treated surface, was a composition (trade name “CLEVIOS PH500” manufactured by H. C. Starck GmbH) for forming an electroconductive layer containing poly(3,4-ethylenedioxythiophene), followed by drying, to form an electroconductive film having a thickness of about 500 nm. Subsequently, each positive photoresist compositions C-1 to C-6 was coated onto the surface of the electroconductive film by a spin coater and was subjected to pre-baking at a temperature of 100° C. for 10 minutes to form a resist film having a thickness of 3 μm, thereby obtaining a laminated film.

Subsequently, the resist layer was exposed at an exposure dose of 300 mJ/cm² bp using a mask aligner (type name “MA-10” manufactured by MIKASA CO., LTD.) having an ultra-high pressure mercury lamp as a light source, and through a photomask. After that, each resist film was developed at a temperature of 23° C. to 25° C. with a developer of 0.7% potassium hydroxide aqueous solution (concentration of potassium ion was 0.125 mol/l). It was then washed by water and dried, to form a resist pattern.

Shown in Table 5 is each result of observation as to whether a trace of close contact of the photomask was left on the surface of the resist film after the photomask was strongly and closely contacted with the resist film upon exposure, and whether abnormalities such as roughness were found on a surface of the obtained resist pattern. In the case of using the positive type photoresist composition C-6, although a trace of close contact of the photomask was found and abnormalities such as roughness were observed on the surface of the resist pattern, these were at such a level that the process of pattern formation of the electroconductive polymer was possible. In the case of using the other positive type photoresist compositions C-1 to C-5, traces of close contact of the photomask were not found, and the surface of each resist pattern was flat and smooth without any abnormalities such as roughness.

TABLE 5

| | Resist | Trace of | Surface roughness |
|---|---|---|---|
| | composition | adherence | of resist pattern |
| Experimental | C-1 | none | none |
| Example 22 | | | |
| Experimental | C-2 | none | none |
| Example 23 | | | |
| Experimental | C-3 | none | none |
| Example 24 | | | |
| Experimental | C-4 | none | none |
| Example 25 | | | |
| Experimental | C-5 | none | none |
| Example 26 | | | |
| Experimental | C-6 | observed | observed |
| Example 27 | | | |

### 5. Formation and Evaluation of Electroconductive Pattern

### Examples 1 to 3

Coated onto a polyethylene terephthalate film (thickness 200 μm) having a corona treated surface, was a composition (trade name “CLEVIOS PH500” manufactured by H. C. Starck GmbH) for forming an electroconductive layer containing poly(3,4-ethylenedioxythiophene), followed by drying, to form an electroconductive film having a thickness of about 500 nm. After that, coated onto the surface of the electroconductive layer by a spin coater was the positive type photoresist composition C-3 in Example 1, the positive type photoresist composition C-4 in Example 2, and the positive type photoresist composition C-5 in Example 3, followed by pre-baking at a temperature of 90° C. for 15 minutes to form each resist film having a thickness of 3 μm.

Subsequently, the resist layer was exposed at an exposure dose of 300 mJ/cm² by using a mask aligner (type name “MA-10” manufactured by MIKASA CO., LTD.) having an ultra-high pressure mercury lamp as a light source, and through a photomask. After that, each resist film was developed with an aqueous solution (concentration of potassium ion was 0.194 mol/l), as a developer, containing potassium hydroxide and potassium carbonate dissolved therein so as to achieve concentrations of potassium ion at 0.100 mol/l and 0.094 mol/l, respectively. Then, washing with water and drying were conducted to form resist patterns each having a cross-sectional structure shown in FIG. 3.

Thereafter, an etching solution was used which is a mixed solution of 10% cerium ammonium nitrate and 10% nitric acid while each resist pattern was used as a mask, to etch the uncovered electroconductive film portion at a temperature of 30° C. The residual resist film portion was then removed using γ-butyrolactone as a stripping agent. Subsequently, washing with water and drying were conducted to obtain substrates each formed with a pattern of electroconductive polymer having a cross-sectional structure shown in FIG. 1. When the formed patterns of the electroconductive polymer were observed with a microscope, all the patterns were formed to be excellent.

In the case of using the positive type photoresist compositions C-9, C-10, C-11, and C-12, when a developer containing potassium ion at a concentration of 0.08 mol/l to 0.20 mol/l and coexistent sodium ion at a concentration of less than 0.1 mol/l is used, a pattern of electroconductive polymer can also be preferably formed.

### 6. Formation and Evaluation of Electroconductive Film

### Experimental Example 28

A composition (trade name “CLEVIOS PH500” manufactured by H. C. Starck GmbH) for forming an electroconductive layer containing poly(3,4-ethylenedioxythiophene) was coated with a bar coater onto a polyethylene terephthalate film (thickness 200 μm) having a corona treated surface. Then drying was conducted to form an electroconductive film having a thickness of 500 nm and obtain a film (s) having an electroconductive layer.

After that, the positive type photoresist composition C-1 was coated onto the surface of the electroconductive layer of the film (s) having the electroconductive layer by a spin coater, and followed by pre-baking at a temperature of 90° C. for 15 minutes to form a resist film having a thickness of 3 μm.

Subsequently, the resist layer was exposed at an exposure dose of 200 mJ/cm² by using a mask aligner (type name “MA-10” manufactured by MIKASA CO., LTD.) having an ultra-high pressure mercury lamp as a light source, and through a photomask. The resist film was then developed at a temperature of 25° C. for 10 seconds with a developer of an aqueous solution containing potassium ion at a concentration of 0.100 mol/l, to uncover the electroconductive film and obtain a film (t) having a resist layer and an electroconductive layer.

After that, the volume resistivity of the electroconductive layer was measured at the center portion of the film (s) having the electroconductive layer by means of an insulation resistance measuring method according to JIS K6911, thereby calculating an electrical conductivity (S/cm). The electrical conductivity of the uncovered electroconductive film in the film (t) was not measured.

### Experimental Examples 29 and 30

A composition was used in which NMP or DMSO was added as an enhancer to a composition (trade name “CLEVIOS PH500” manufactured by H. C. Starck GmbH) for forming an electroconductive layer containing poly(3,4-ethylenedioxythiophene) so as to be solely 5% relative to the whole of the composition.

The composition for forming an electroconductive layer was coated with a bar coater onto a polyethylene terephthalate film (thickness 200 μm) having a corona treated surface. Then drying was conducted to form an electroconductive layer having a thickness of 500 nm and obtain a film (s) having the electroconductive layer.

After that, a film (t) was obtained having a resist layer and an electroconductive layer, in the same manner as Experimental Example 28. Then, a volume resistance of the electroconductive film was measured at a central part of the film (s) having the electroconductive layer and film (t) to calculate conductivity (S/cm). The result was shown in Table 6.

### Experimental Example 31

Obtained was a film (t) in the same manner as Experimental Example 30, except that a developer was used which contained no potassium ions and had a sodium ion in a concentration of 0.100 mol/l. After that, a volume resistance of the electroconductive film was measured at a central part of the film (s) having the electroconductive layer and film (t) to calculate conductivity (S/cm). The result was shown in Table 6.

### Experimental Example 32

A film (t) having a resist layer and an electroconductive layer was obtained in the same manner as those in Experimental Example 30 except that a developer containing TMAH at a concentration of 0.90% and containing no potassium ion. After that, a volume resistance of the electroconductive film was measured at a central part of the film (s) having the electroconductive layer and film (t) to calculate conductivity (S/cm). The result was shown in Table 6.

TABLE 6

| | | | Conductivity | |
|---|---|---|---|---|
| | | | (S/cm) | |
| | | | Before | After |
| | Enhancer | Developer | development | development |
| Experimental | — | KOH | 0.3 | — |
| Example 28 | | | | |
| Experimental | DMSO (5%) | KOH | 30 | 15 |
| Example 29 | | | | |
| Experimental | NMP (5%) | KOH | 30 | 15 |
| Example 30 | | | | |
| Experimental | NMP (5%) | NaOH | 30 | 12 |
| Example 31 | | | | |
| Experimental | NMP (5%) | TMAH | 30 | 12 |
| Example 32 | | | | |

Although an electrical conductivity of an electroconductive layer was notably improved when an enhancer was added, the electrical conductivity was lowered to a certain extent when the electroconductive layer was contacted with a developer. Nonetheless, when a developer containing a potassium ion at the predetermined concentration was used, the lowered extent of the electrical conductivity was less, in a manner to enable to obtain a remarkably higher electrical conductivity even after contact with the developer, as compared to the case without an enhancer.

### Experimental Example 33

Obtained was a film (t) in the same manner as Experimental Example 30, except that calcium chloride as a protective agent was added into the developer. After that, a volume resistance of the electroconductive film was measured at a central part of the film (s) having the electroconductive layer and film (t) to calculate conductivity (S/cm). The result was shown in Table 7.

### Experimental Example 34

Obtained was a film (t) in the same manner as Experimental Example 30, except that polyoxyethylene tridecyl ether (trade name “Newcol N1305” manufactured by Nippon Nyukazai Co., Ltd.) as a protective agent was added into the developer. After that, a volume resistance of the electroconductive film was measured at a central part of the film (s) having the electroconductive layer and film (t) to calculate conductivity (S/cm). The result was shown in Table 7.

### Experimental Example 35

Obtained was a film (t) in the same manner as Experimental Example 32, except that calcium chloride as a protective agent was added into the developer. After that, a volume resistance of the electroconductive film was measured at a central part of the film (s) having the electroconductive layer and film (t) to calculate conductivity (S/cm). The result was shown in Table 7.

### Experimental Example 36

Obtained was a film (t) in the same manner as Experimental Example 32, except that polyoxyethylene tridecyl ether (trade name “Newcol N1305” manufactured by Nippon Nyukazai Co., Ltd.) as a protective agent was added into the developer. After that, a volume resistance of the electroconductive film was measured at a central part of the film (s) having the electroconductive layer and film (t) to calculate conductivity (S/cm). The result was shown in Table 7.

TABLE 7

| | | | Conductivity | |
|---|---|---|---|---|
| | | | (S/cm) | |
| | | | Before | After |
| | Developer | Additive | development | development |
| Experimental | KOH | CaCl₂ (5%) | 30 | 17 |
| Example 33 | | | | |
| Experimental | KOH | N1305 (0.01%) | 30 | 17 |
| Example 34 | | | | |
| Experimental | TMAH | CaCl₂ (5%) | 30 | 14 |
| Example 35 | | | | |
| Experimental | TMAH | N1305 (0.01%) | 30 | 14 |
| Example 36 | | | | |

N1305: Polyoxyethylene tridecylether

The electroconductive film containing an enhancer added therein was considerable in deterioration of the electrical conductivity of an electroconductive layer even after contact with a developer. When an additive was formulated into the developer, the deterioration of the electrical conductivity of the electroconductive layer could be restricted after contact with the developer to realize a higher electrical conductivity.

### INDUSTRIAL APPLICABILITY

The method for forming a pattern of an electroconductive polymer of the present invention utilizes productions of a transparent electroconductive film, an organic EL device, a solar cell, and the like as an alternative to ITO containing a rare element.

1-9. (canceled)

10. A method for forming a pattern of an electroconductive polymer, comprising sequentially,
forming an electroconductive layer by adding a composition comprising an electroconductive polymer on a surface of a base body,
forming a film by coating a positive type photoresist composition onto a surface of said electroconductive layer to form a positive type photoresist film,
heating said positive type photoresist film,
exposing the resist film obtained by said heating in a manner that at least part of a surface of said resist film disposed on the surface of said electroconductive layer is kept unexposed,
removing the exposed portion obtained by said exposing with a developer to uncover an electroconductive layer,
removing the uncovered electroconductive layer portion, and
removing the remaining resist film portion,
wherein said positive type photoresist composition comprises a naphthoquinone diazide compound and a novolak resin, and
wherein said developer comprises a potassium ion at a concentration of 0.08 mol/l to 0.20 mol/l, and a coexistent sodium ion at a concentration of less than 0.1 mol/l.

11. The method for forming a pattern of an electroconductive polymer according to claim 10, wherein said positive type photoresist composition comprises said naphthoquinone diazide compound, said novolak resin, and a polyvinyl methyl ether.

12. The method for forming a pattern of an electroconductive polymer according to claim 11, wherein a calculational value E (° C.) is in the range from 60° C. to 110° C., said calculational value is calculated by the following equation (1) based on a softening point A (° C.) of said novolak resin and a content B (parts by weight) of said novolak resin, and a glass transition temperature C (° C.) of said polyvinyl methyl ether and a content D (parts by weight) of said polyvinyl methyl ether:
B/{100×(273+A)}+D/{100×(273+C)}=1/(273+E) (1)
(in the equation, B+D=100).

13. The method for forming a pattern of an electroconductive polymer according to claim 11, wherein said electroconductive polymer is a polythiophene or a polypyrrole.

14. The method for forming a pattern of an electroconductive polymer according to claim 13, wherein said polythiophene is a poly(3,4-ethylenedioxythiophene).

15. The method for forming a pattern of an electroconductive polymer according to claim 14, wherein said developer comprises at least one compound selected from the group consisting of a polyoxyethylene alkyl ether and a halogenide of an alkaline earth metal.

16. The method for forming a pattern of an electroconductive polymer according to claim 15, wherein said composition for forming an electroconductive layer comprises a solvent having a boiling point of 100° C. or higher at an atmospheric pressure.

17. The method for forming a pattern of an electroconductive polymer according to claim 10, wherein said electroconductive polymer is a polythiophene or a polypyrrole.

18. The method for forming a pattern of an electroconductive polymer according to claim 17, wherein said polythiophene is a poly(3,4-ethylenedioxythiophene).

19. The method for forming a pattern of an electroconductive polymer according to claim 18, wherein said developer comprises at least one compound selected from the group consisting of a polyoxyethylene alkyl ether and a halogenide of an alkaline earth metal.

20. The method for forming a pattern of an electroconductive polymer according to claim 19, wherein said composition for forming an electroconductive layer comprises a solvent having a boiling point of 100° C. or higher at an atmospheric pressure.

21. The method for forming a pattern of an electroconductive polymer according to claim 10, wherein said developer comprises at least one compound selected from the group consisting of a polyoxyethylene alkyl ether and a halogenide of an alkaline earth metal.

22. The method for forming a pattern of an electroconductive polymer according to claim 10, wherein said composition for forming an electroconductive layer comprises a solvent having a boiling point of 100° C. or higher at an atmospheric pressure.

23. A plate having a pattern of an electroconductive polymer wherein said plate is obtained by a process comprising utilizing said method for forming a pattern of an electroconductive polymer according to claim 10.
